(19) United States
(12) Patent Application Publication
(10) Pub. No.: US 2022/0244638 A1
(43) Pub. Date: Aug. 4, 2022

(54) CONDUCTIVE PATTERNING USING A PERMANENT RESIST

(71) Applicant: TEXAS INSTRUMENTS INCORPORATED, Dallas, TX (US)

(72) Inventors: Hidetoshi Inoue, Oyama (JP); Kenji Kawano, Kita Saku (JP); Yuki Sato, Kita-ku (JP); Takafumi Ando, Beppu (JP); Michael Lueders, Freising (DE); Stefan Herzer, Marzling (DE); Jeffrey Morroni, Parker, TX (US)

(21) Appl. No.: 17/512,959

(22) Filed: Oct. 28, 2021

Related U.S. Application Data
(60) Provisional application No. 63/143,632, filed on Jan. 29, 2021.

(51) Int. Cl. G03F 7/00; H01L 21/027

(52) U.S. Cl. CPC G03F 7/0035; H01L 21/0274

(57) ABSTRACT

A permanent resist, such as TMMF, is used when patterning conductive material on a substrate, enabling lines that have a higher line-to-space ratio (L/S) or a higher aspect ratio (T/L) or both. Pattern density can thus be increased, allowing for improved performance (e.g., greater efficiency, in the case of transformer coil patterning) and greater heat dissipation. As examples, the permanent-resist-based patterning fabrication methods can be used to create transformer coils within an integrated circuit (IC) module, or a routable lead frame for one or more IC dies.

### CROSS-REFERENCE TO RELATED APPLICATION

This application claims priority to U.S. provisional patent application No. 63/143,632, filed 29 Jan. 2021, which is hereby incorporated by reference.

### TECHNICAL FIELD

This description relates generally to electronic circuit fabrication, and more particularly to conductive patterning using a permanent resist.

### BACKGROUND

Patterning processes such as a subtractive etch process, a semi-additive process (SAP), and a modified semi-additive process (MSAP) can be used in fabrication of integrated circuits (ICs), printed circuit boards (PCBs), and printed wiring boards (PWBs) to lay fine traces of a conductive material, such as copper, in order to provide conductive lines that serve as wires in an electronic circuit product. A subtractive etch process starts with a laminate consisting of, for example, polyimide and copper, typically one-quarter ounce or greater. The circuit pattern is then formed by depositing copper and then etching away unwanted copper. SAP and MSAP, by contrast, utilize additive processing operations, adding copper to a base dielectric to create a circuit pattern. Pattern density can be measured, for example, by a ratio of line width to line space width (L/S) in a pattern.

A lead frame is a structure inside an IC package that carries signals from an IC die inside the package to the outside of the package. A lead frame can include, for example, a central die pad, upon which the die is glued or soldered; bond pads, where bond wires are placed to connect the die to parts inside of the package and outside of the die; metal leads that connect the inside of the package with the outside; and mechanical connections to fix these parts inside a frame structure. The coupled die and lead frame can be molded in molding compound to form the completed IC package. Standard lead frames may have the metal leads on only a single layer. By contrast, a routable lead frame (RLF) is a lead frame that includes a multilayer routable substrate, e.g., a molded interconnect substrate (MIS), on which the leads are formed by traces that are routed, e.g., under and/or over one another, through an etching process, providing higher density, reduction of package size, and improved thermal dissipation over earlier lead frame designs.

### SUMMARY

An example method includes patterning a seed layer of a conductive material on a substrate. A layer of permanent resist is laminated over the patterned seed layer to a thickness. A photolithographic mask is mounted over the layer of permanent resist. The layer of permanent resist is exposed to a light and developed to pattern the layer of permanent resist. Portions of the patterned seed layer are thus exposed through the removed portions of the permanent resist. An additional amount of the conductive material is plated over the patterned seed layer to create individual traces or coiled windings of one or more traces. The individual traces or the windings are spaced apart from each other by at least a space width. The individual traces or the windings have a minimum width of the conductive material that is at least a line width. The individual traces or the windings have a minimum height of the conductive material. Some example methods can further include forming additional patterned layers of the conductive material with the permanent resist.

An example device includes a layer of conductive material patterned into individual traces or coiled windings. At least some of the traces or windings are lined with walls of a permanent resist that extend up to at least a minimum height of the at least some of the traces or windings. The individual traces or the windings are spaced apart from each other by at least a space width. The individual traces or the windings have a minimum width of the conductive material that is at least a line width. Some example devices further include a second layer of patterned conductive material that is also formed to include a permanent resist as walls of the second-layer patterning. The layer of patterned conductive material can be integrated into at least one IC module comprising at least one IC die that is electrically coupled to at least one of the traces or coiled windings.

### BRIEF DESCRIPTION OF THE DRAWINGS

FIG. 1 is a cross-section of example conductive patterning having a first conductive trace and a second conductive trace on a non-conductive substrate.

FIG. 2 is a cross-section of example conductive patterning fabricated using a permanent resist, having conductive traces separated by the permanent resist.

FIGS. 3A-3G are cross-sectional diagrams illustrating an example subtractive method for conductive trace patterning.

FIGS. 4A-4G are cross-sectional diagrams illustrating an example SAP fabrication process.

FIGS. 5A-5G are cross-sectional diagrams illustrating an example MSAP fabrication process.

FIGS. 6A-6F are cross-sectional diagrams illustrating an example permanent-resist-based patterning process.

FIGS. 7A-7H are cross-sectional diagrams illustrating an example seed layer patterning process that can be used in the permanent-resist-based patterning process of FIGS. 6A-6F.

FIG. 8 is a drawing of a micrographic perspective view of example high-aspect-ratio copper patterning.

FIG. 9 is a drawing of a micrographic cross-sectional view of example copper patterning.

FIG. 10 is a cross-sectional diagram of an example transformer coil patterning.

FIG. 11A is a top-down view of an example transformer IC package.

FIG. 11B is a cross-sectional view of the example transformer IC package of FIG. 11A.

FIGS. 12A-12T are cross-sectional diagrams illustrating an example permanent-resist-based patterning process used to create a transformer coil.

FIG. 13 is a cross-sectional diagram of an example RLF patterning.

FIG. 14A is an oblique view of example patterning lines on an RLF substrate.

FIG. 14B is a cross-sectional view of one of the example patterning lines of FIG. 14A.

FIG. 14C is an oblique view of example patterning lines on an RLF substrate created using a permanent-resist-based patterning process.

FIG. 14D is a cross-sectional view of one of the example patterning lines of FIG. 14C.

FIGS. 15A-15V are cross-sectional diagrams illustrating an example permanent-resist-based patterning process used to create a portion of an RLF.

FIG. 16 is graph of line heights versus line space widths for example trace patterns produced using subtractive, SAP, and MSAP methods as compared to a permanent-resist-based patterning process.

FIG. 17 is a flow chart of an example permanent-resist-based patterning process.

### DETAILED DESCRIPTION

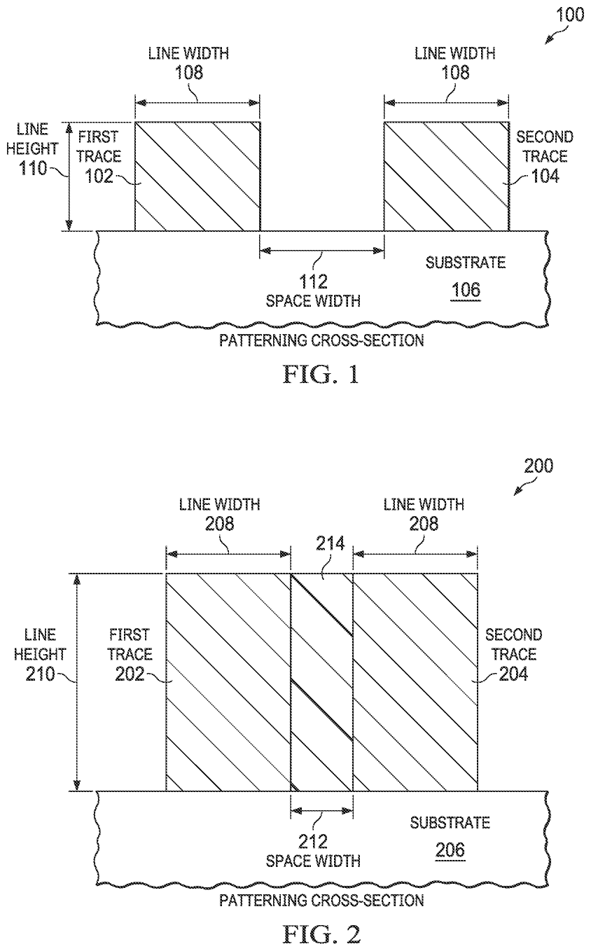

FIG. 1 is a cross-section illustration of example conductive patterning 100 having a first conductive trace 102 and a second conductive trace 104 on a non-conductive substrate 106. The two traces 102, 104 can, in some examples, be two parallel portions of the same conductive trace, as when forming separate windings of a transformer coil. Each trace 102, 104 has a line width 108, sometimes referred to in the art simply as “line” or “L”, and a line height 110, which can also be referred to as a line thickness or “T”. Traces 102, 104 have between them a space width 112, sometimes referred to in the art simply as “space” or “S”, which can be substantially uniform over the lengths of the traces 102, 104.

Increasingly sophisticated electronics benefit from patterning processes capable of producing finer conductive lines and narrower spaces between these conductive lines. The trend of miniaturization of IC dies has meant that IC packages are likewise being fabricated to be smaller and of higher power density. Making finer the conductive trace patterning of IC substrates can help achieve higher performance, or higher efficiency in the case of transformers, even for small package sizes. Increasing the height of conductive trace patterning and narrowing the spaces between patterning traces can improve heat dissipation and can also reduce the size of an IC package. However, subtractive, SAP, and MSAP patterning methods all result in relatively large spaces, such as space 112, between the patterning traces, such as traces 102, 104 in FIG. 1. These patterning methods pose limits to the distances that inter-trace spaces can be narrowed while still maintaining line widths and line heights. For example, the subtractive method of circuit patterning is typically limited to production of features having line widths (e.g., line width 108) and inter-line spacing widths (e.g., space width 112) of between about 60 micrometers and about 100 micrometers or greater.

In devices and methods described herein, patterning is formed using a permanent resist. A permanent resist is a permanent photodefineable dielectric used to create an image on a surface of a printed circuit product that remains at least in part as an integral part of the printed circuit product and is not totally stripped away, even if it may be partially ground down. Because the permanent resist can remain within a finished circuit product as permanent film, lines of the patterning in the circuit product are insulated from each other, and higher aspect ratio patterning can be formed. It is thus possible to form pattering with a high aspect ratio that cannot be achieved by existing patterning formation methods such as the subtractive method, SAP, or MSAP, alone. The cross-section of FIG. 2 illustrates the higher aspect ratio as compared with FIG. 1. First and second traces 202, 204 in example patterning 200 are formed to have a permanent resist material 214 between them. First and second traces 202, 204 are higher, as noted by line height 210 being higher as compared with line height 110 in FIG. 1, and are closer together on substrate 206, as noted by space width 212 being reduced as compared to space width 112 in FIG. 1. Line widths 208 in FIG. 2 are not substantially eroded or reduced as compared to line widths 108 in FIG. 1.

As one example, an IC package produced using the methods described herein can be made smaller and have higher performance by forming conductive trace patterning with a high aspect ratio in a narrow space using a permanent resist, which can increase the occupied area of conductive trace patterning and improve heat dissipation and desired functions. As another example, an inductive coil formed using conductive trace patterning according to the methods described herein can have higher efficiency than otherwise achievable with existing patterning formation methods.

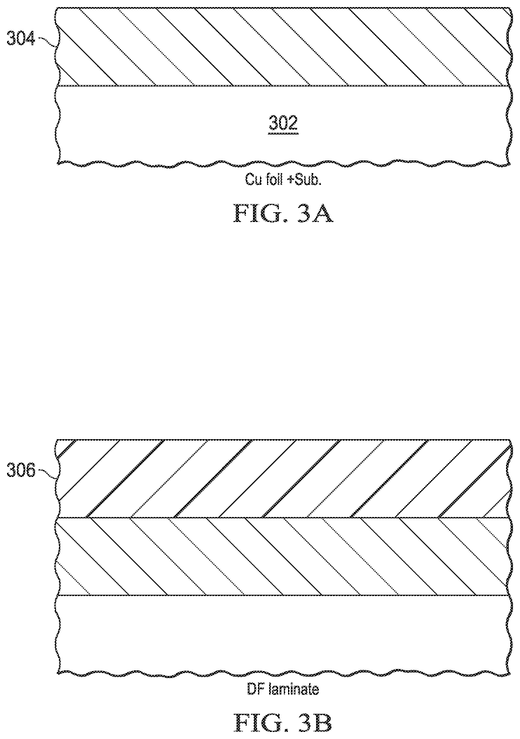

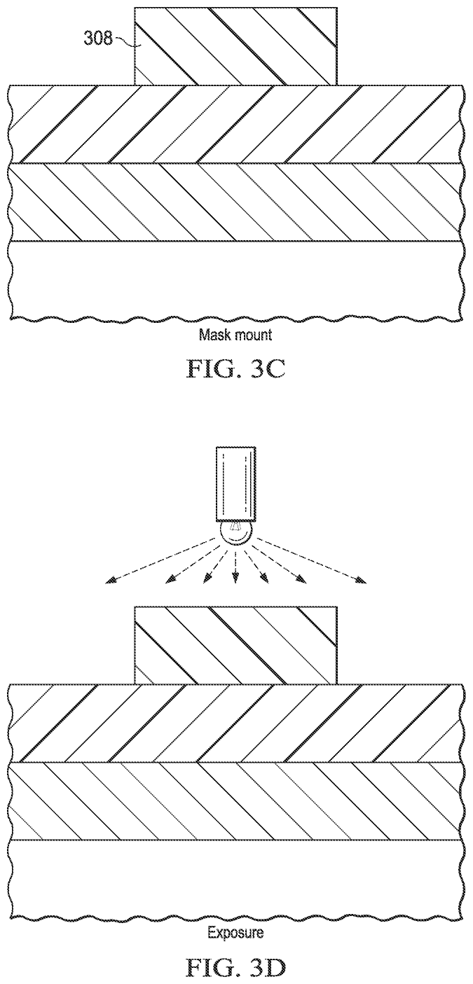

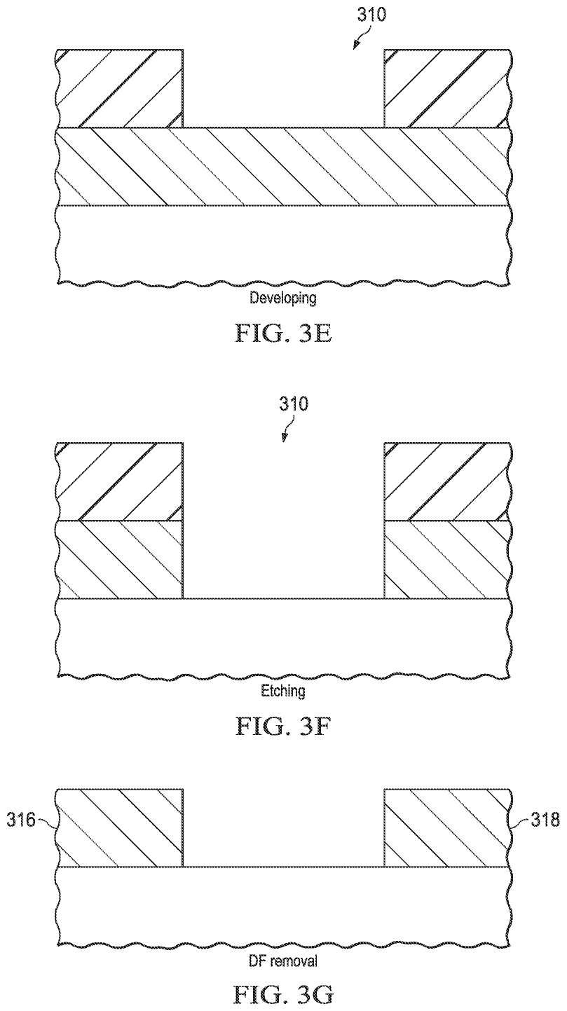

FIGS. 3A through 3G illustrate an example of fabrication of conductive patterning according to a subtractive method. In the examples that follow, the conductive material that forms the patterned traces is described as copper, but it will be understood that other conductive materials may be used in place of copper in other examples. In FIG. 3A, a copper foil 304 is formed over a substrate 302. In FIG. 3B, a layer of dry film 306 is laminated over the copper foil 304. The subtractive, SAP, and MSAP methods described herein use negative dry film, as opposed to positive dry film. Negative dry film cures when exposed to light. In FIG. 3C, a mask layer 308 is mounted over the dry film 306 to pattern the surface. Patterning is followed by exposure to a light source in FIG. 3D and developing in FIG. 3E to remove portions of the dry film 306 in locations, such as location 310, where the mask layer 308 was placed. Etching by a chemical treatment follows in FIG. 3F to remove copper in the locations where the mask layer 308 had been placed and where the dry film 306 is absent, such as location 310. In FIG. 3G, the remaining dry film 306 is removed to result in the patterning that includes separate copper traces 316, 318. The subtractive method shown in FIGS. 3A through 3G has the drawback that the chemical treatment used to vertically etch the lines 316, 318 dissolves the copper not only in the vertical direction but also in the horizontal direction along the trace walls. This horizontal dissolution of the conductive material can result in traces that can appear slightly trapezoidal in shape as viewed in cross-section, for example, with sides at an included angle from the base of between about 25° and about 45°, which can pose impedance reliability issues at millimeter-wave frequencies as used in 5G technologies.

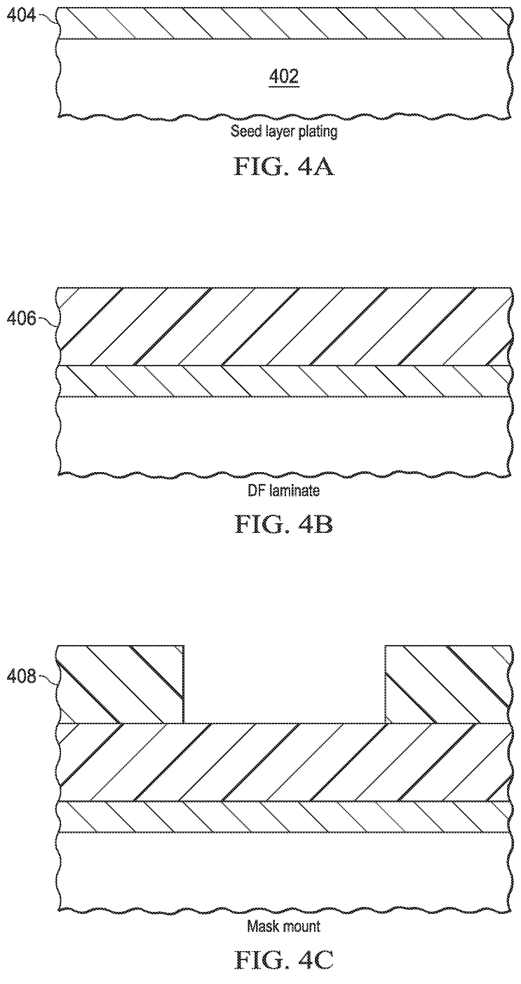

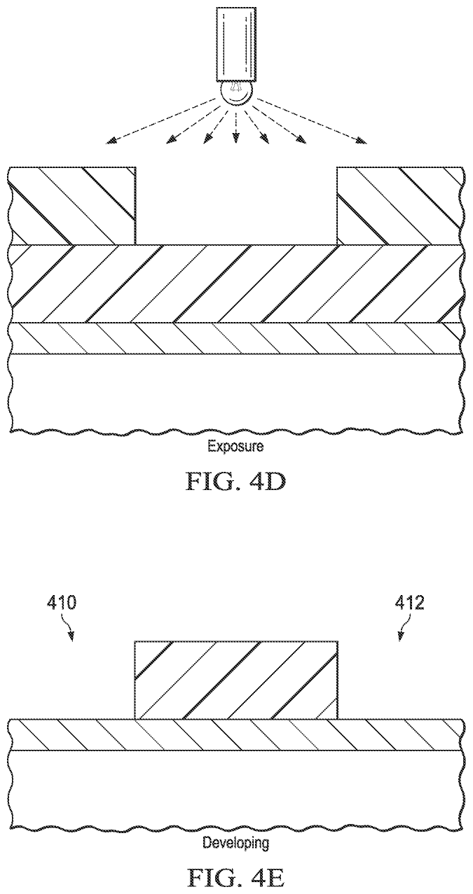

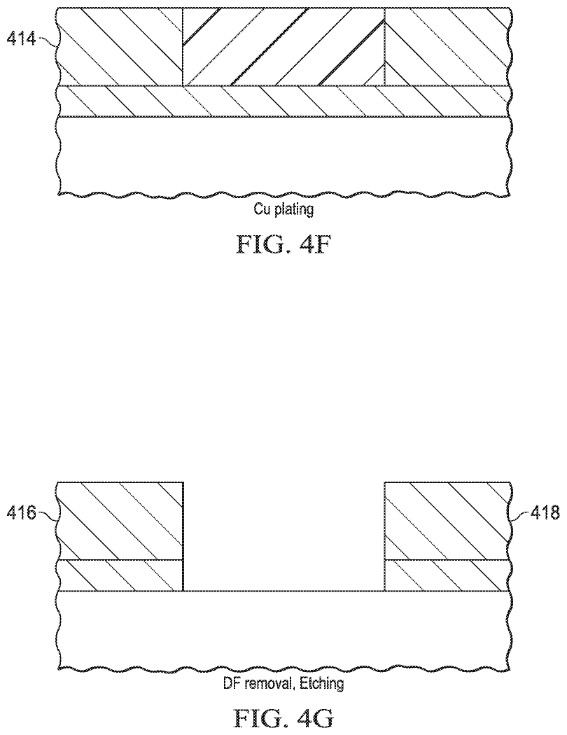

FIGS. 4A through 4G illustrate an example of fabrication of conductive patterning according to an SAP method. In FIG. 4A, a seed layer 404 of electroless copper is plated over a substrate 402, to a thickness that can be substantially thinner than the foil layer 302 used in the subtractive process of FIGS. 3A-3G. For example, the thickness of the seed layer 404 can be less than about 1.5 micrometers. In FIG. 4B, a layer of dry film 406 is laminated over the seed layer 404. In FIG. 4C, a mask layer 408 is mounted over the dry film 406 to pattern the surface. Unlike with the subtractive method of FIGS. 3A-3G, in the SAP method illustrated in FIGS. 4A-4G, the mask layer 408 is mounted over locations where the eventual traces will be formed, rather than locations where conductive material will be removed to form the spaces between traces. Patterning is followed by exposure to a light source in FIG. 4D and developing in FIG. 4E to remove portions of the dry film 406 in locations, such as locations 410 and 412, where the mask layer 408 was placed. In FIG. 4F, additional copper 414 is plated (e.g., electroplated) to the desired thickness, up to the height of the top of the dry film 506, over the exposed seed layer 404 in the locations 410, 412 where the mask layer 408 had been placed and where the dry film 406 is absent. In FIG. 4G, the remaining dry film 406 is removed using a release agent and the un-built-up portion of the seed layer 404 is etched away to result in the patterning that includes separate copper traces 416, 418. The method shown in FIGS. 4A-4G is “semi-additive” in that some, but not all, of the copper traces 416, 418 results from an additive plating as shown in FIG. 4F.

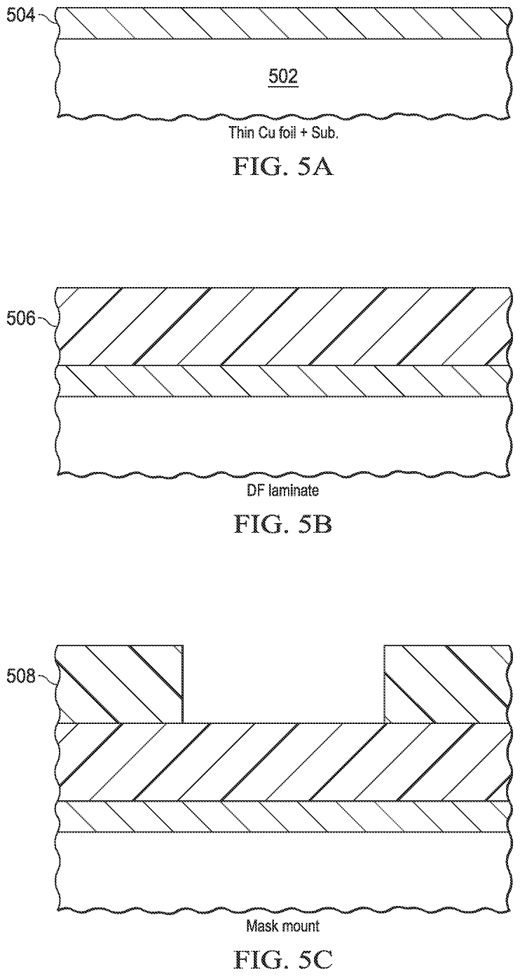

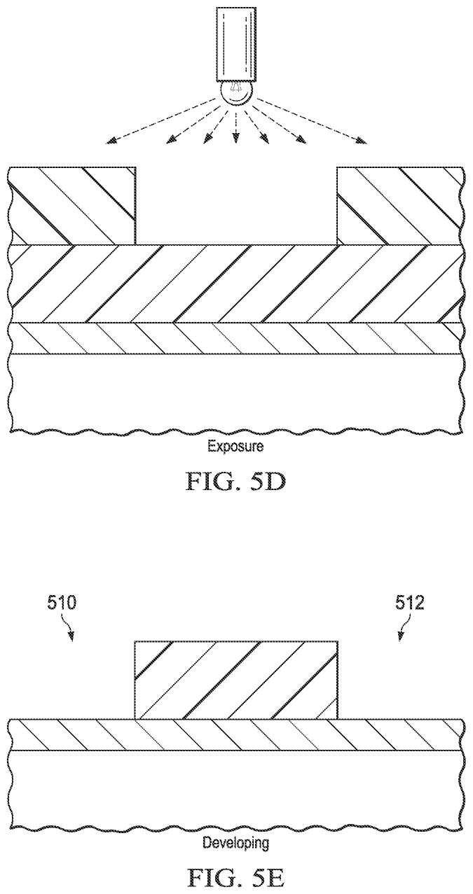

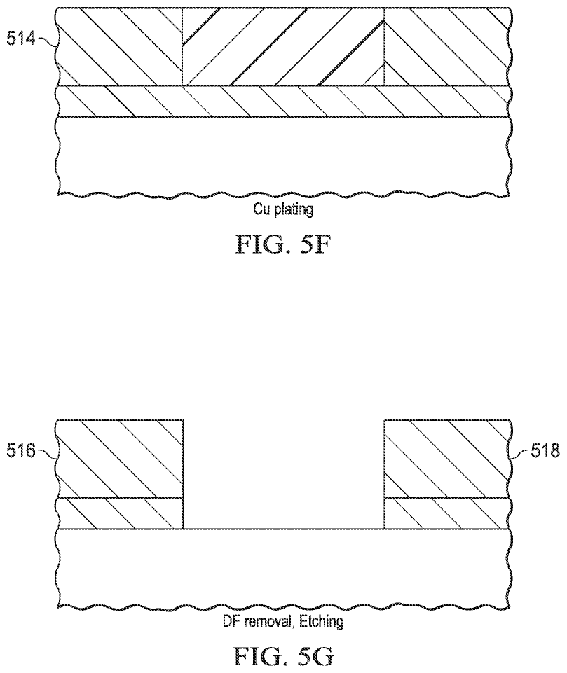

The example MSAP method illustrated in FIGS. 5A through 5G follows the same manufacturing process as the SAP method of FIGS. 4A-4G, with the exception that the thin laminated copper foil layer 504 laid down on the substrate 502 in FIG. 5A is thicker than the seed layer 404 in the SAP method (while still being thinner than the foil 304 in the subtractive method). For example, foil layer 504 can be of a thickness of greater than about 1.5 micrometers. In FIG. 5B, a layer of dry film 506 is laminated over the foil layer 504. In FIG. 5C, a mask layer 508 is mounted over the dry film 506 to pattern the surface. Patterning is followed by exposure to a light source in FIG. 5D and developing in FIG. 5E to remove portions of the dry film 506 in locations, such as locations 510 and 512, where the mask layer 508 was placed. In FIG. 5F, additional copper 514 is plated (e.g., electroplated) to the desired thickness over the exposed foil layer 504 in the locations 510, 512 where the mask layer 508 had been placed and where the dry film 506 is absent. In FIG. 5G, the remaining dry film 506 is removed using a release agent and the un-built-up portion of the foil layer 504 is etched away to result in the patterning that includes separate copper traces 516, 518. The major difference between the SAP and MSAP methods as compared to the subtractive method is that the copper patterning is followed by plating. Line height can thus be substantially increased over what is possible in the subtractive method without the adverse erosion effects of the etching process that tend to make trapezoid in shape the trace cross-sections.

However, difficulties are posed when trying to form a high patterning height in a narrow space using subtractive, MSAP, and SAP methods. In the subtractive method, the etching process (e.g., in FIG. 3F) can require a long time when forming patterning with a high line height, and the resultant patterning can be undesirably thin in terms of line width. In the SAP and MSAP methods, the maximum line height is controlled by the thickness of the dry film (406 or 506 in the illustrated examples). However, if the dry film is too thick, the exposure light (e.g., in FIGS. 4D and 5D) will not reach the bottom of the dry film during exposure, and the resultant patterning will be physically and electrically connected, with lines sticking together. Moreover, when removing the dry film (e.g., in FIGS. 4G and 5G), the liquid release agent can fail to reach the bottom of the dry film, and dry film can remain on the substrate, if the dry film layer is too thick. Consequently, with subtractive, SAP, and MSAP methods, traces cannot be produced with higher aspect ratios while maintaining or reducing space widths. For example, these methods cannot produce traces having line heights of greater than about 40 micrometers, e.g., greater than about 50 micrometers, e.g., greater than about 100 micrometers, while maintaining line space widths below about 50 micrometers. As another example, these methods are not capable of producing traces having line heights of greater than about 10 micrometers while maintaining line space widths of less than about 30 micrometers, e.g., less than about 10 micrometers. As a result, it may not be possible, using subtractive, SAP, and MSAP fabrication methods, to increase pattern density (PD) or suppress heat generation as package sizes become increasingly smaller.

Patterning height can be increased in a narrow space by using a permanent resist for permanent structure formation. An example permanent resist is the proprietary film produced by Tokyo Ohka Kogyo Co., Ltd. (TOK), and known as TMMF (the trade name of a permanent, epoxy-based dry film photoresist) or TMMR (the trade name of a permanent, epoxy-based liquid photoresist). For example, the permanent resist can be used instead of a general dry film and, rather than being removed during the fabrication process, can be left in place after the conductive patterning is formed, remaining intact in the completed patterned circuit product. Examples of general dry films include RD series films, produced Showa Denko Materials, and Sunfort series films, produced by Asahi Kasei. Other examples of permanent resist films include SU-8 series films and KMPR series films, produced by Nippon Kayaku. Permanent-resist-based fabrication methods as described herein are capable of, for example, producing lines having heights of about 40 micrometers or more with line space widths of less than about 30 micrometers, e.g., less than about 10 micrometers. The permanent-resist-based fabrication methods described herein can be used, for example, for transformer coil patterning, or for patterning in an RLF. In a transformer coil, the coil patterning can be made denser, with coils patterned in a narrower space, and the transformer can be improved in performance, with higher inductance and efficiency. In an RLF, higher and thicker patterning can improve thermal dissipation, and as a result, the package footprint may be made smaller and the output current can be reduced.

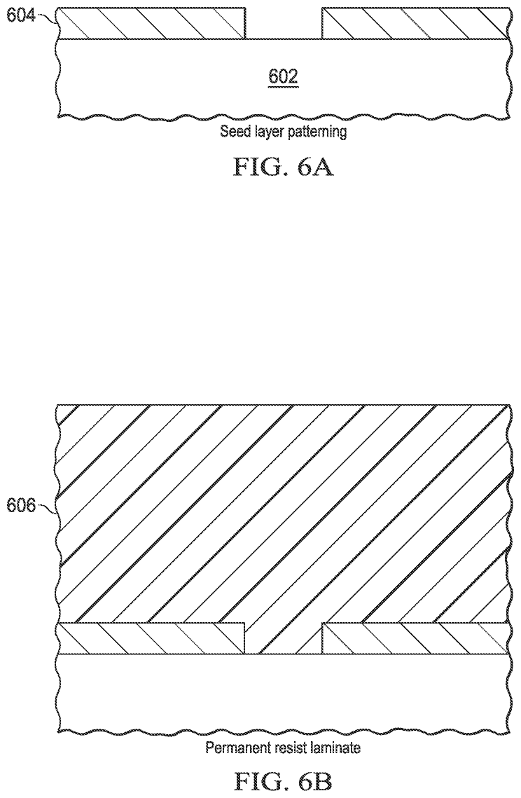

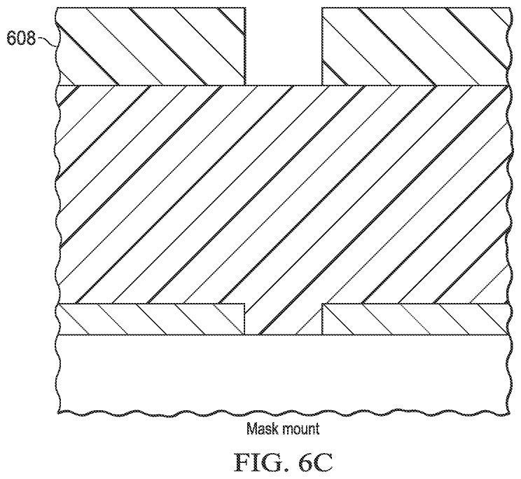

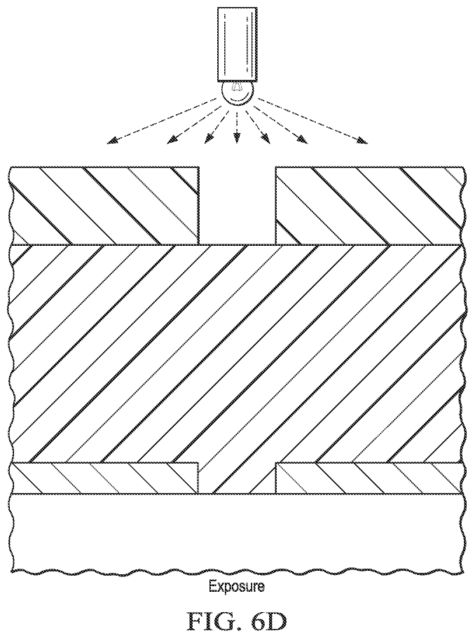

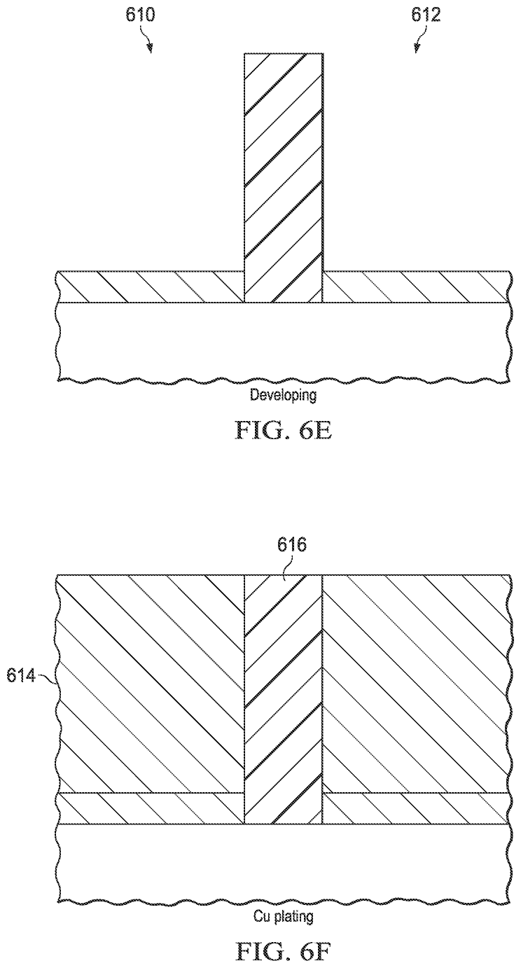

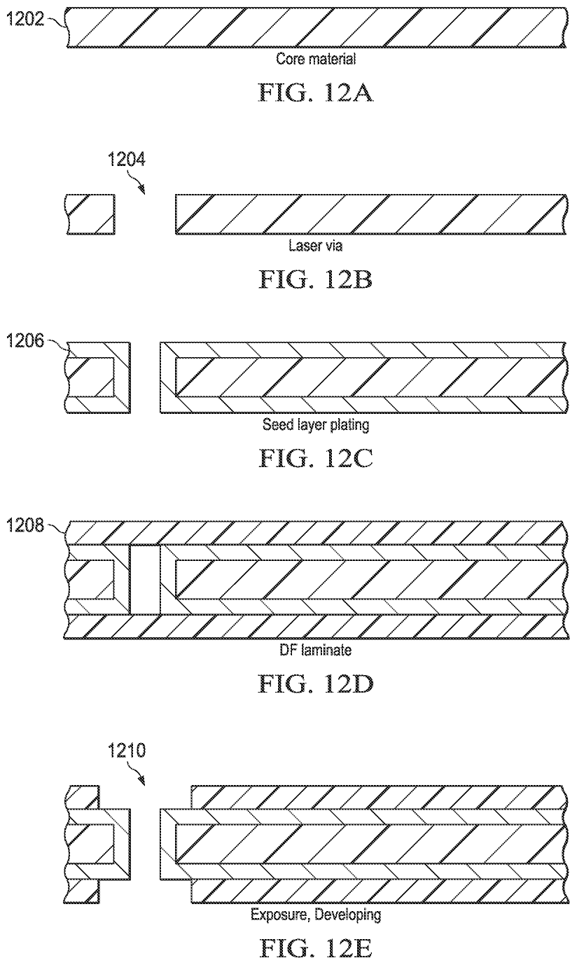

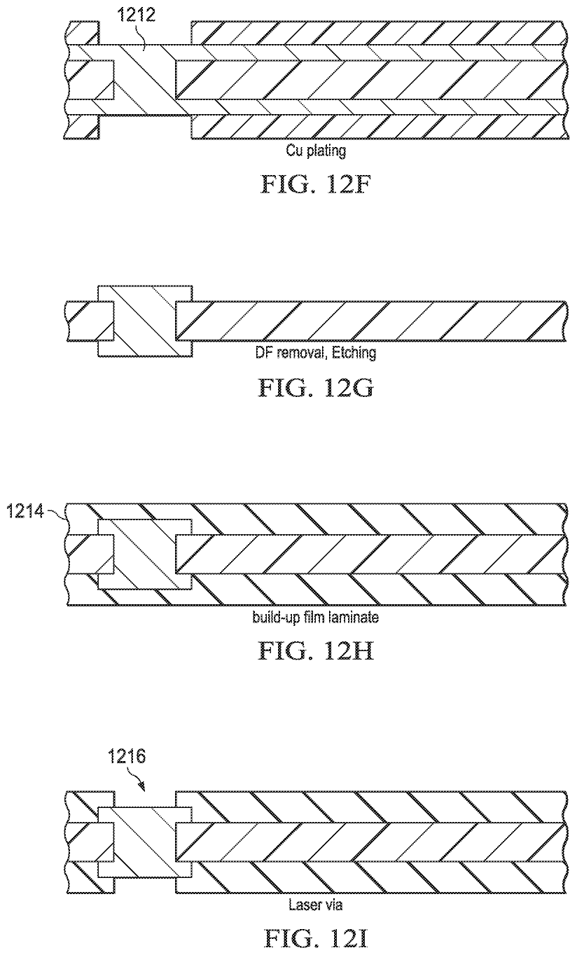

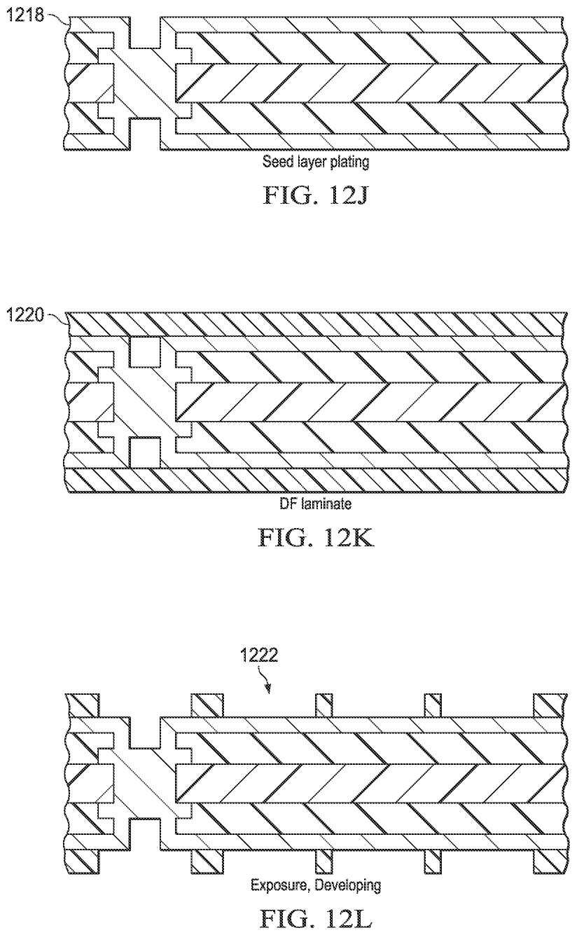

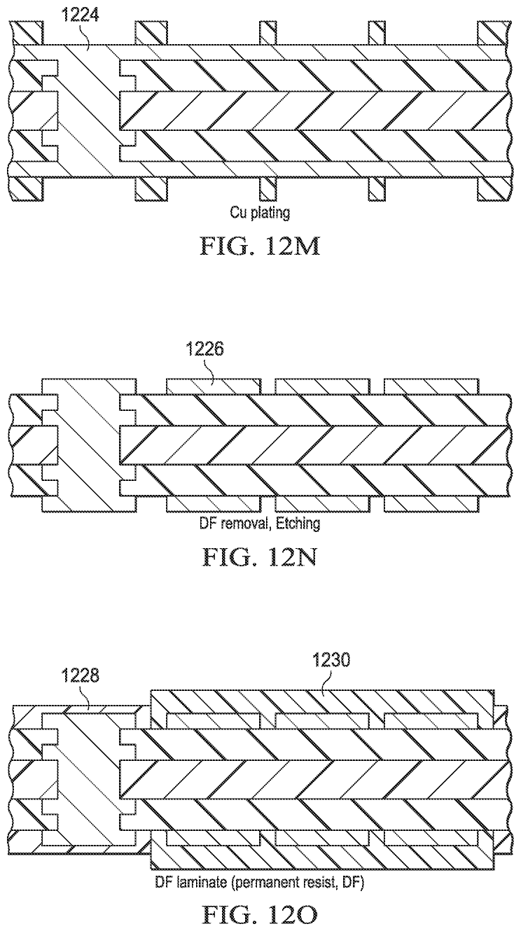

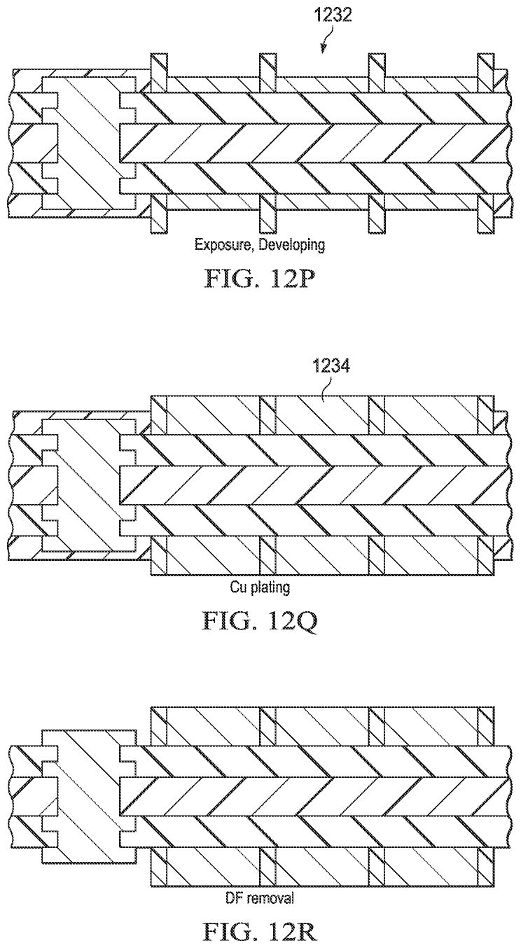

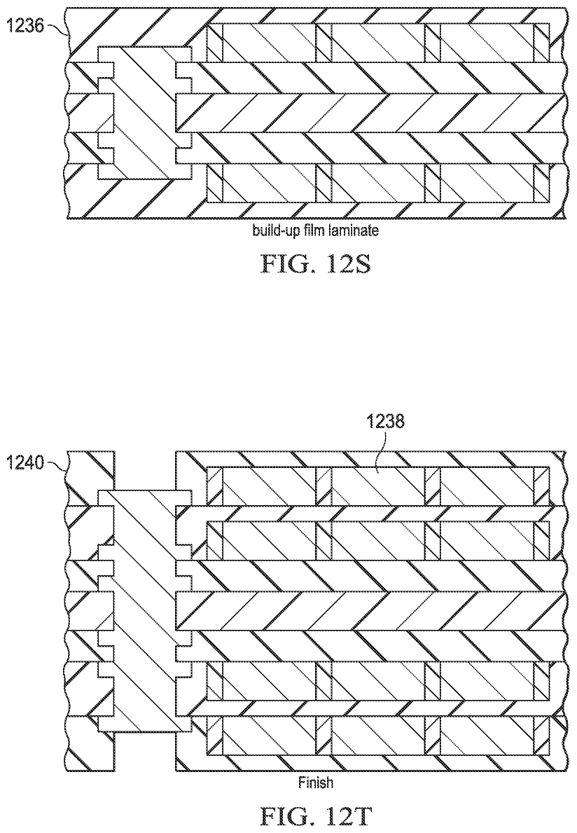

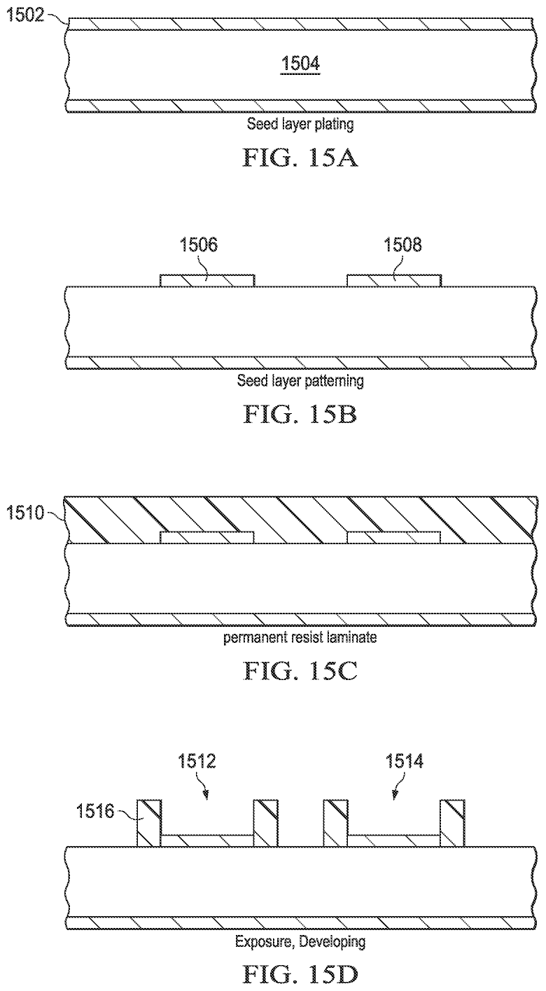

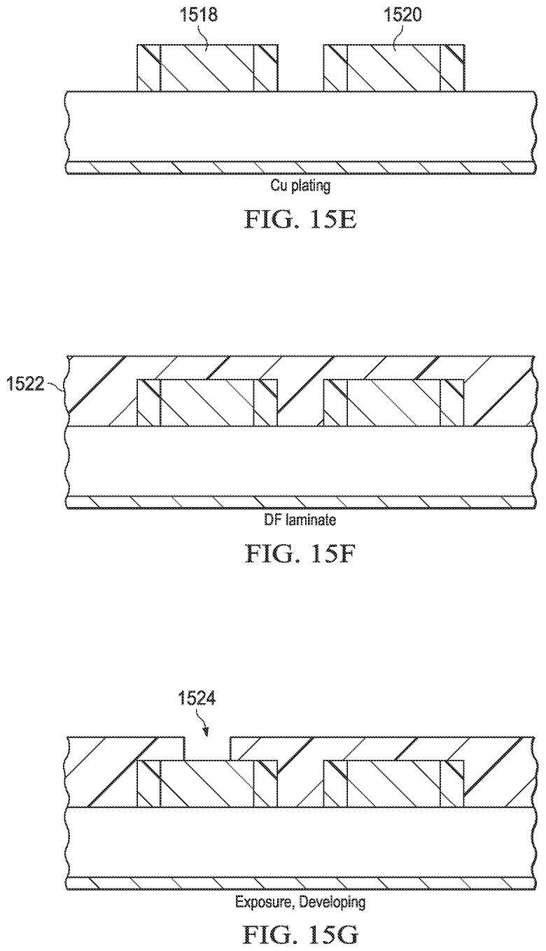

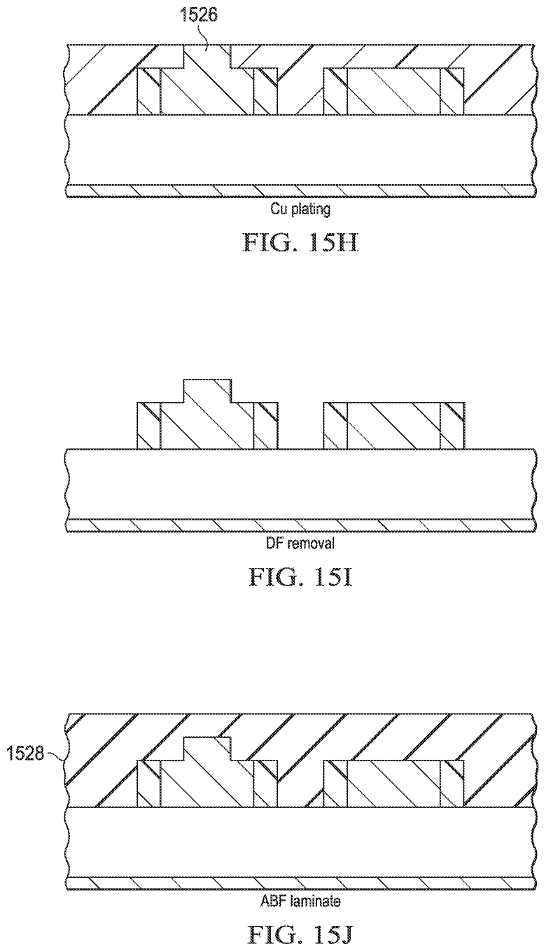

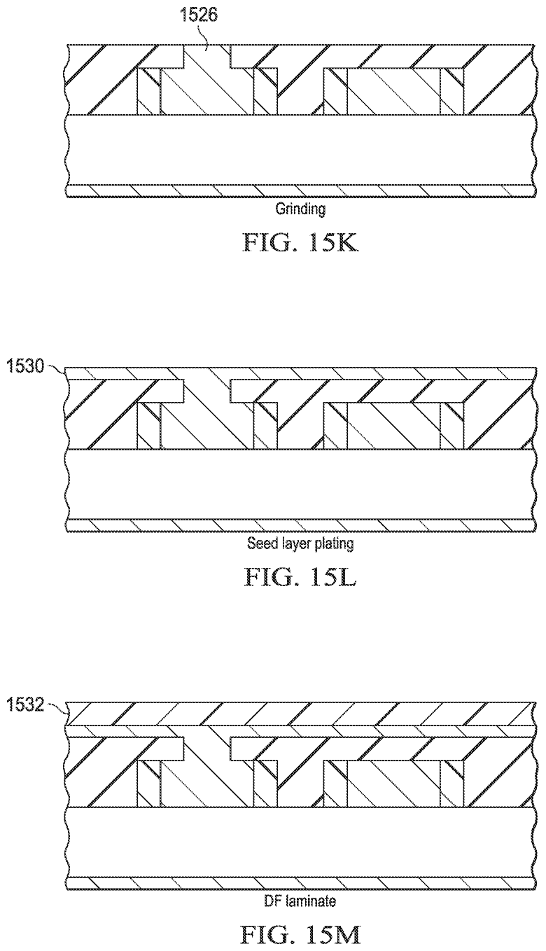

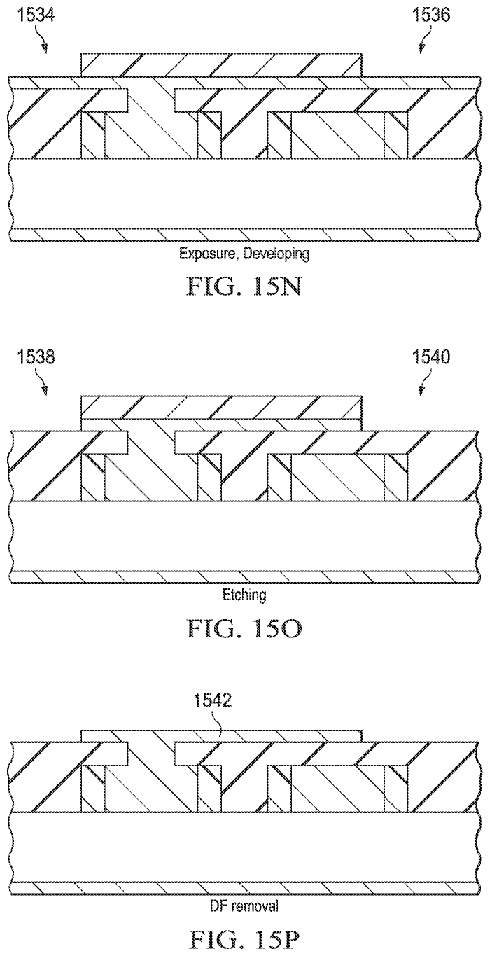

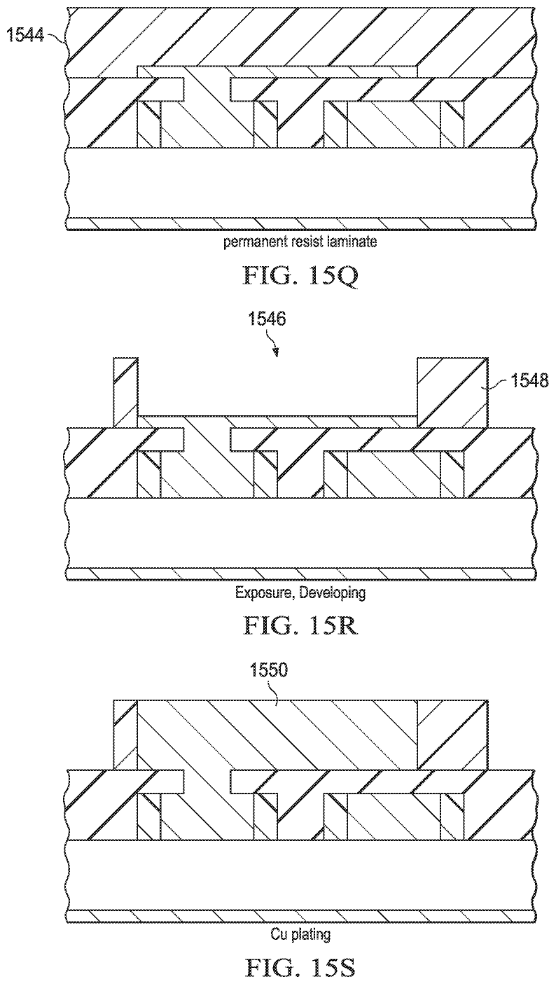

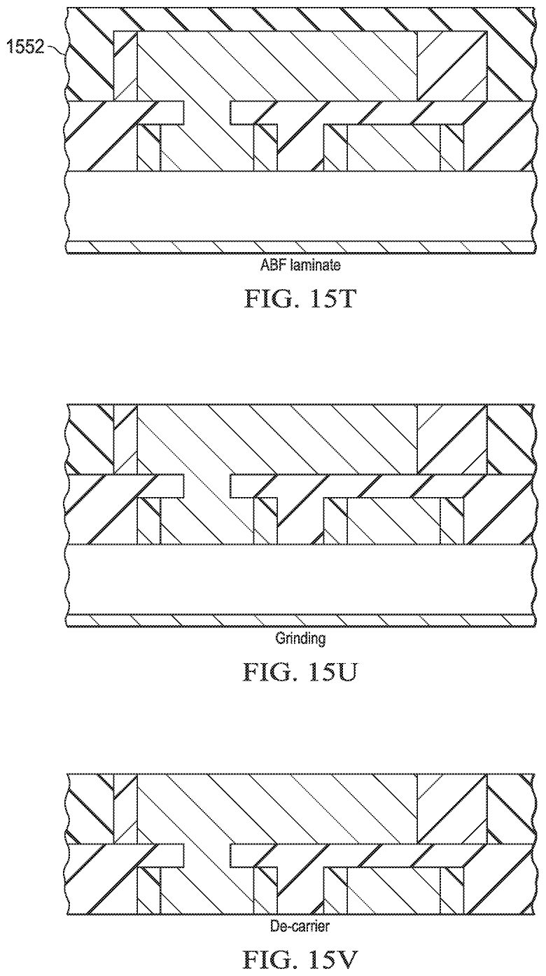

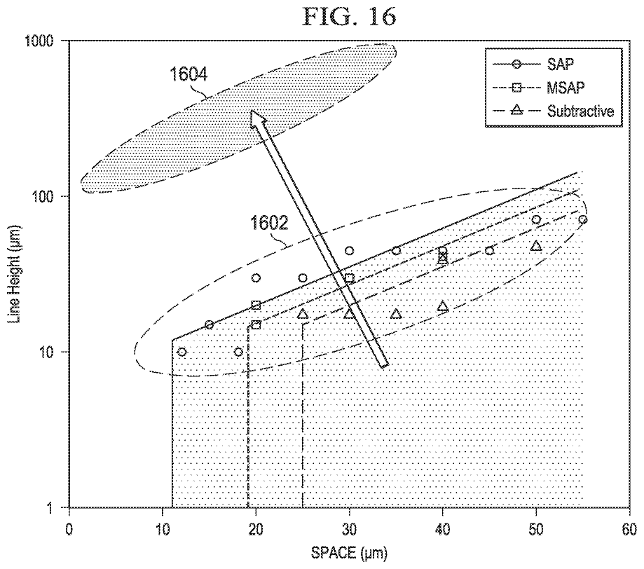

The cross-sectional diagrams of FIGS. 6A through 6F illustrate an example processing method that uses a permanent resist to fabricate high-aspect-ratio patterning with narrow space widths. As shown in FIG. 6A, in contrast to the SAP method, the seed layer 604 is patterned after being formed (e.g., electroplated) on a substrate 602. In some examples, such as the example method shown in FIGS. 12A-12T, the substrate 602 can be a dielectric substrate, and thus can remain as part of the finished circuit product. In other examples, such as the example method shown in FIGS. 15A-15V, the substrate 602 can be a conductive substrate that is subsequently removed and thus does not remain as part of the finished circuit product.

As shown in FIG. 6B, a permanent resist 606 is deposited to the thickness of the desired patterning height. In FIG. 6C, a mask layer 608 is mounted over the permanent resist 606 to pattern the surface. Patterning is followed by exposure to a light source in FIG. 6D and developing in FIG. 6E to remove portions of the permanent resist 606 in locations, such as locations 610 and 612, where the mask layer 608 was placed. In FIG. 6F, additional copper 614 is plated (e.g., electroplated) to the desired thickness over the exposed seed layer 604 in the locations 610, 612 where the mask layer 608 had been placed and where the dry film 606 is absent. The remaining interstitial permanent resist 616 is not removed but remains in place to result in the finished patterning in which traces are separated by permanent resist that serves to electrically insulate the traces. This permanent-resist-based process also does not include an etch to chemically remove copper after the plating of FIG. 6F.

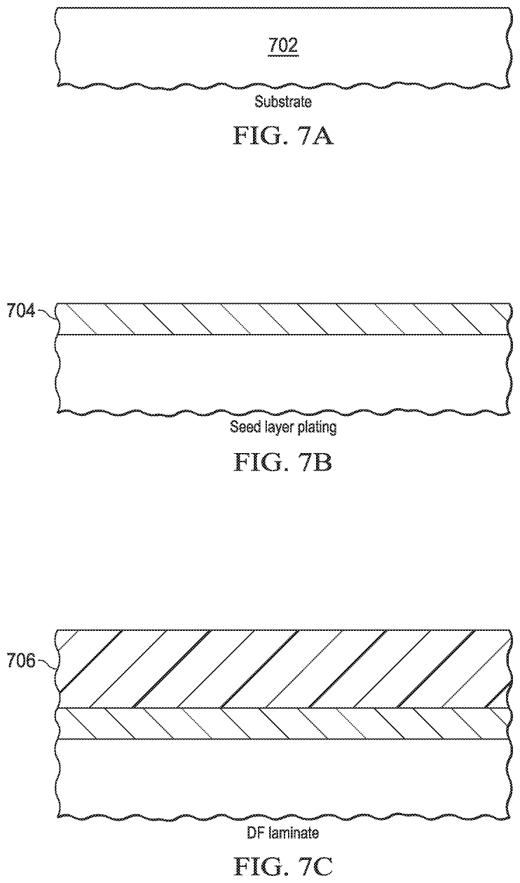

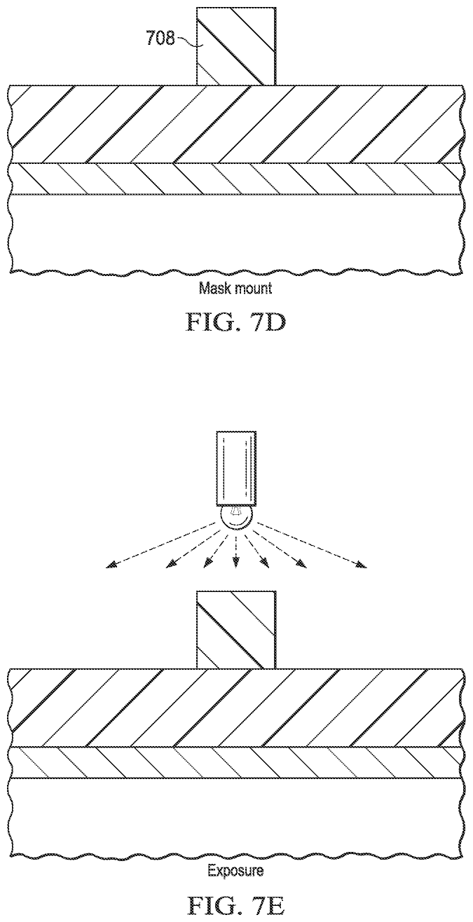

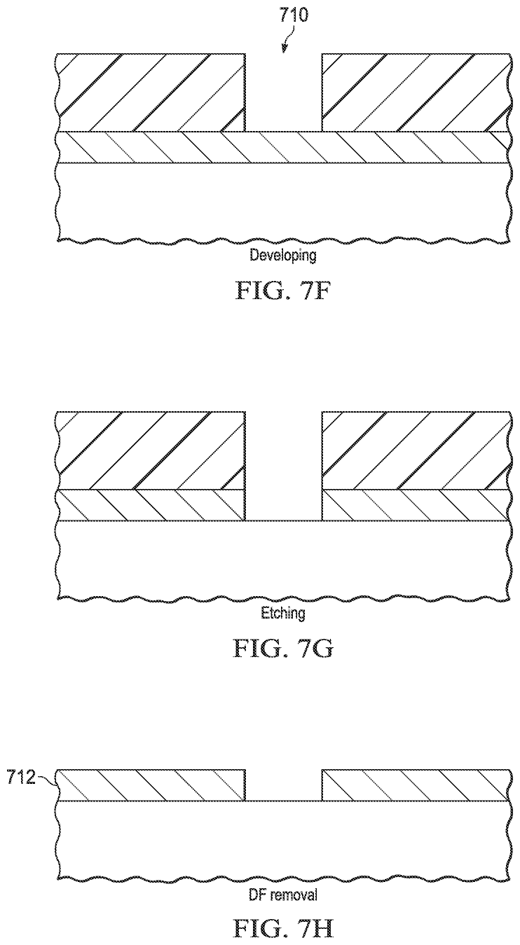

As illustrated in FIGS. 7A through 7H, the seed layer patterning of FIG. 6A can be performed using a subtractive process that resembles the process illustrated FIGS. 3A-3G, except that the patterned copper layer is a thin seed layer, e.g., having a thickness of less than about 1.5 micrometers, rather than being a foil having a thickness of about the desired line height. The seed layer patterning process begins in FIG. 7A with a substrate 702, over which a copper seed layer 704 is formed in FIG. 7B. In FIG. 7C, a layer of dry film 706 is laminated over the copper foil 704. In FIG. 7D, a mask layer 708 is mounted over the dry film 706 to pattern the surface. Patterning is followed by exposure to a light source in FIG. 7E and developing in FIG. 7F to remove portions of the dry film 706 in locations, such as location 710, where the mask layer 708 was placed. Etching by a chemical treatment follows in FIG. 7G to remove copper in the locations where the mask layer 708 had been placed and where the dry film 706 is absent, such as location 710. In FIG. 7H, the remaining dry film 706 is removed to result in the seed layer patterning as shown, for example, in FIG. 6A.

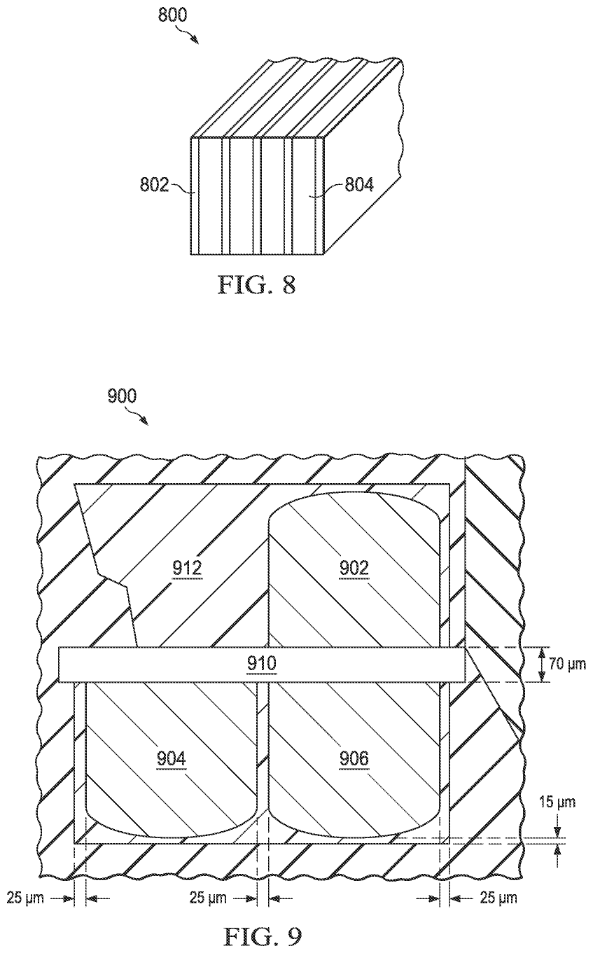

FIG. 8 is a perspective view 800 from a micrograph of example high-aspect-ratio conductive traces 802 having permanent resist 804, between the traces 802 for permanent structure formation, allowing for high patterning height and narrow space patterning. For example, the line height can be greater than about 40 micrometers with the ratio of line width to space width L/S being greater than about 10, e.g., greater than about 15.

FIG. 9 is a cross-sectional view 900 from a micrograph of example conductive traces 902, 904, 906 on either side of a substrate 910 that is about 70 micrometers thick. The use of permanent resist 912 allows the traces 904, 906 to exhibit a line width to space width ratio L/S than would otherwise be possible with subtractive, SAP, or MSAP fabrication methods, e.g., about 350 micrometers to about 20 micrometers. As shown the illustrated example, traces 904 and 906 are about 25 micrometers apart from each other, even though the line height of the traces is much greater than about 40 micrometers, e.g., greater than about 50 micrometers, e.g., greater than about 100 micrometers, e.g., about 280 micrometers, as shown in FIG. 9.

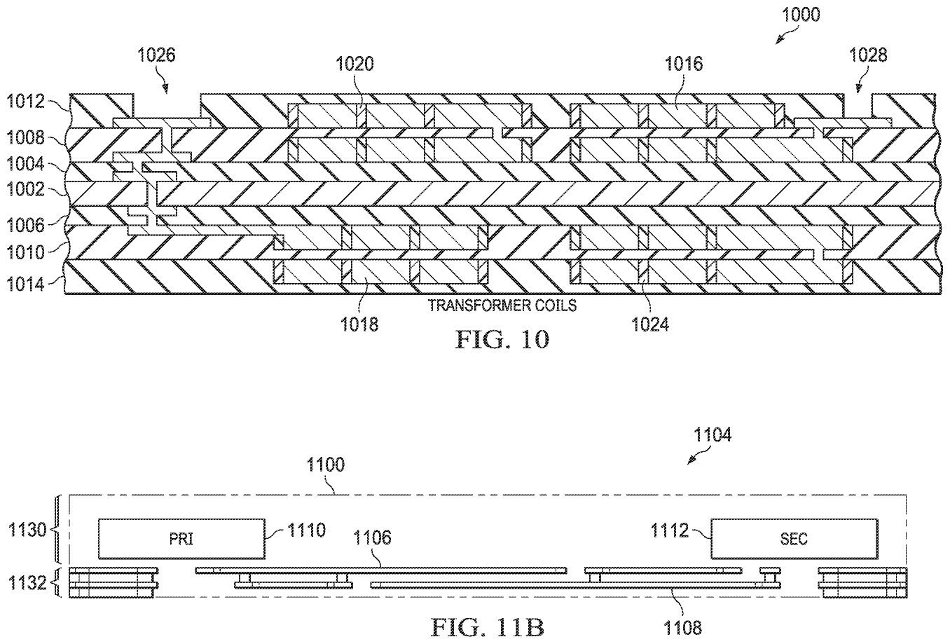

FIG. 10 is a cross-sectional diagram of an example transformer coil patterning fabricated according to the permanent-resist-based patterning method described above with reference to FIGS. 6A-7F. Layers of dielectric substrate 1004, 1006, 1008, 1010, 1012, 1014 are formed on either side of a dielectric core layer 1002 and have embedded therein conductive traces (e.g., traces 1016, 1018) separated from each other by permanent resist (e.g., permanent resist 1020, 1024). Windows (e.g., windows 1026, 1028) in the top substrate layer 1012 permit conductive contact to the respective primary and secondary coils. The process that can be used to form the transformer of FIG. 10 is described further with regard to FIGS. 12A-12T.

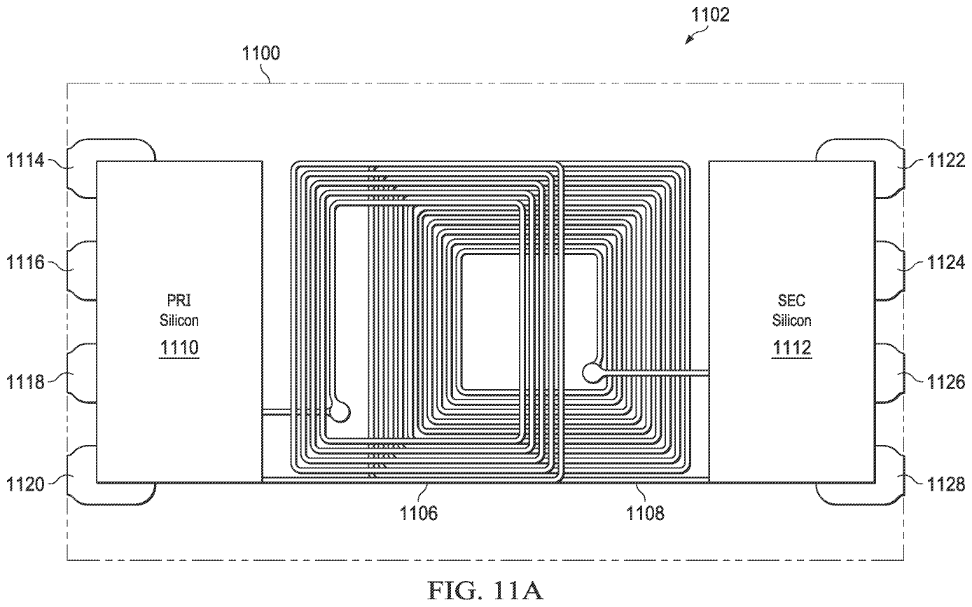

An example transformer IC package 1100 is shown in a first, top-down view 1102 in FIG. 11A and a cross-sectional view 1104 in FIG. 11B. The primary coil 1106 and the secondary coil 1108 can be fabricated according to a permanent-resist-based method as described herein for greater transformer efficiency. The primary coil 1106 is coupled at respective ends of the primary coil 1106 to a primary die 1110 that can include electronic devices used, for example, to drive currents in the primary coil 1106, and that can be fabricated using silicon-based processing techniques. The secondary coil 1108 is coupled at respective ends of the secondary coil 1108 to a secondary die 1112 that can include electronic devices used, for example, to receive currents driven in the secondary coil 1108, and that can also be fabricated using silicon-based processing techniques. Transformer IC 1100 can in some examples be bidirectional such that power or signals are at times transferred from the primary side to the secondary side and at other times transferred from the secondary side to the primary side. As shown in the cross-sectional view 1104 of FIG. 11B, an upper portion 1130 of the transformer IC 1100 can be encapsulated in a mold, e.g., a plastic mold, while a lower portion 1132 of the transformer IC 1100, containing the terminals 1114, 1116, 1118, 11120, 1122, 1124, 1126, 1128 can be formed at least in part from a build-up film, such as Ajinomoto Build-up Film (ABF) interlayer insulating materials. Coils 1106, 1108 can be fabricated using a permanent-resist-based method and can be formed as shown in the cross-section of FIG. 10.

FIGS. 12A through 12T are cross-sectional diagrams illustrating an example permanent-resist-based patterning process used to create transformer coils. Only a portion of the coils is illustrated in the process of FIGS. 12A-12T; the illustrated process can be extended to form a complete coil structure as shown, for example, in FIG. 10. Some intermediate parts of the process, such as photolithographic mask mounts and resin cures, are omitted for simplicity of illustration. The fabrication process begins in FIG. 12A with a core material 1202, which can be, for example, an epoxy laminate material such as are used in PCB board fabrication. As an example, core material 1202 can be a composite material composed of woven fiberglass cloth with an epoxy resin binder. The layer formed by core material 1202 can correspond, for example, to the core layer 1002 of FIG. 10. In FIG. 12B, a laser is used to cut a via 1204 completely through the core material 1202 at the eventual location of a conductive connection 1212, 1224 between the two sides of the core material 1202. In FIG. 12C, a sputter of a conductive metal, such as copper, is used to plate a seed layer 1206 onto the core material 1202. In FIG. 12D, a layer of dry film 1208, which can be a thick-film photoresist material, is laminated over the seed layer 1206. FIG. 12E shows the results of exposure and developing following a mask mount, used to eliminate portions of the dry film layer 1208, e.g., at location 1210 of via 1204 from FIG. 12B. In FIG. 12F, copper plating fills in the via 1204 created in FIG. 12B to create the conductive connection 1212 between the two sides of the core material 1202. The copper plating does not build up the portions of the seed layer 1206 that are covered over by the dry film 1208. The remainder of the dry film 1208 is removed, and an etch is performed to remove the un-built-up portions of the seed layer 1206, resulting in the structure shown in FIG. 12G.

The portions of the process shown in FIGS. 12H through 12N, in effect, repeat the portions of the process illustrated by FIGS. 12A-12G to build additional layers of the transformer. In FIG. 12H, both sides of the core material 1202 are laminated with a dielectric substrate material 1214, e.g., a build-up material, e.g., bismaleimide-triazine (BT) epoxy resin, to form layers that can correspond, for example, to layers 1004, 1006 in FIG. 10. FIG. 12I shows additional laser via openings performed to expose the conductive connection at location 1216 on both sides of the core material 1202. FIG. 12J shows plating of a second seed layer 1218, using a process that can be similar or identical to that shown in FIG. 12C to plate the first seed layer 1206. FIG. 12K shows a lamination of a second layer of dry film 1220, in substantially the same or a similar fashion to the lamination of the first layer of dry film 1208 in FIG. 12D. Second mask mount, exposure, and developing procedures result in the structure shown in FIG. 12L, in which portions of the second layer of dry film 1220 are removed in certain locations, such as location 1216, where the through-core electrical connection is to be extended, and locations like location 1222, where the second seed layer 1218 will subsequently be built up with additional plating to form the transformer coils. FIG. 12M shows a fourth plating of conductive material (e.g., copper), like that of FIG. 6F, to create patterns of coils on both sides of the transformer core 1202, and to fill in the through-core electrical connection 1224. The remainder of the second layer of the dry film 1220 is removed, and an etch is performed to remove the un-built-up portions of the second seed layer 1218, resulting in the structure shown in FIG. 12N. The remaining built-up portions of the second seed layer 1218 include the through-core electrical connection 1224 and patterns of coils, such as coil portion 1226 in FIG. 12N, that will subsequently be built up with additional conductive material to form the transformer coils.

In FIG. 120, a third layer of dry film 1228 is laminated over certain portions of both sides of the transformer, and a first layer of permanent resist 1230 (e.g., TMMF) is laminated over other portions of both sides of the transformer. For example, the third layer of dry film 1228 is laminated over the through-core electrical connection 1224, and the permanent resist 1230 is laminated over the partially built-up portions of the patterned seed layer 1218, such as portion 1226, which will eventually become transformer coils. Third mask mount, exposure, and developing procedures result in the structure shown in FIG. 12P, in which the partially built-up portions of the patterned seed layer 1218, such as portion 1226, are exposed for additional plating build-up. FIG. 12Q shows a fifth plating of conductive material (e.g., copper), to increase the height of the patterns of coils on both sides of the transformer core 1202. The through-core electrical connection 1224 is unaffected by the fifth plating of FIG. 12Q because it is covered by the third layer of dry film 1228. The remainder of the third layer of the dry film 1228 is removed, resulting in the structure of FIG. 12R. In FIG. 12S, both sides of the transformer are laminated with a dielectric substrate material 1236, such as a build-up film epoxy resin, to form layers that can correspond, for example, to layers 1008, 1010 in FIG. 10. Portions of the permanent resist 1230 remain in the transformer, separating individual windings of the transformer coils from each other.

The operations of FIGS. 12I through 12S can be repeated, followed by another repetition of the via opening of FIG. 12I, to add an additional coil layer to each side of the transformer, resulting in the structure shown in FIG. 12T. These repetitions are not illustrated, but, in brief, a laser is used to reopen the via to the through-core electrical connection 1224 on each side of the transformer; a third seed layer is plated and patterned using a fourth dry film laminate, mask mount, exposure, developing, playing, dry film removal, and third seed layer etching operations; fifth dry film and second permanent resist layers are formed; openings are made to the partially built-up portions of the third seed layer on both sides of the transformer; the partially built-up portions of the third seed layer are plated to the desired height, resulting in coil windings such as winding 1238; the fifth dry film layer is removed; both sides of the transformer are laminated with a dielectric substrate material 1240, such as a build-up film epoxy resin, that can correspond to layers 1012, 1014 in FIG. 10; and a laser is used to reopen the via to the through-core electrical connection 1224, through the dielectric material 1240 on at least one side. FIG. 12T shows an example finished transformer, which has coils that are connected on each side of the core 1202.

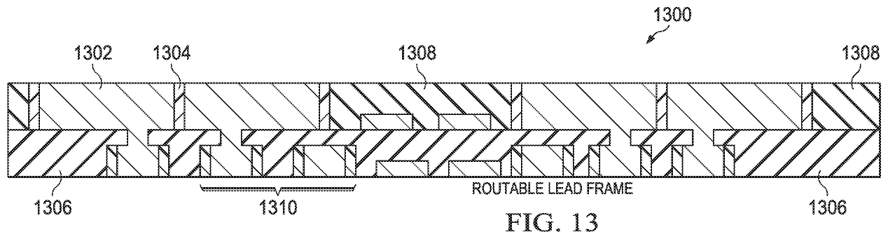

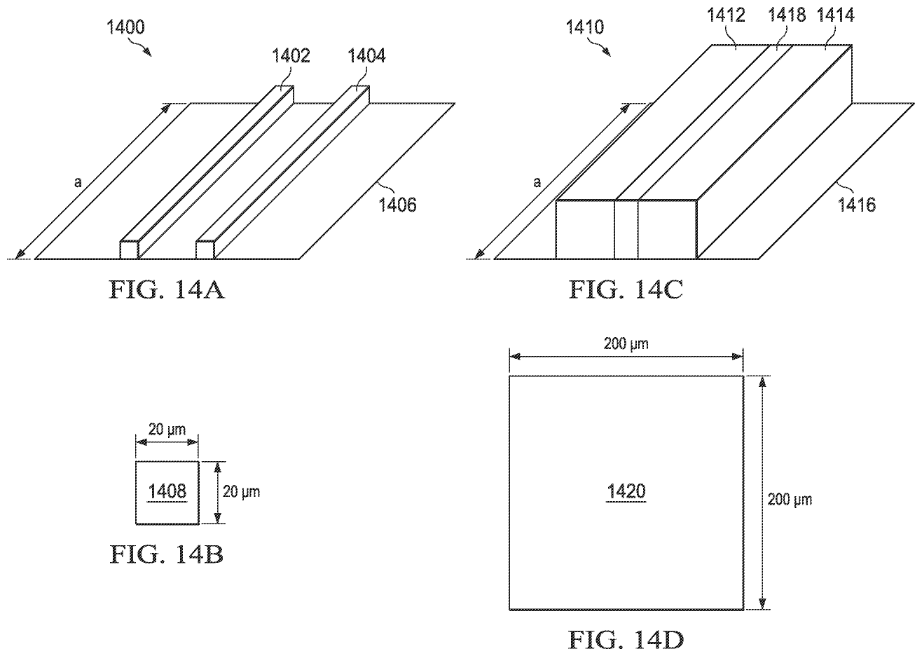

FIG. 13 is a cross-sectional diagram of an example RLF patterning 1300 fabricated using permanent-resist-based methods as described herein. As illustrated by FIGS. 14A-14D, higher and thicker patterning can be achieved using fabrication methods that use a permanent resist than can be achieved using subtractive, SAP, or MSAP methods. The higher and thicker patterning can improve thermal dissipation. As a result, the footprint of the RLF may be smaller. RLF patterning 1300 includes conductive portions 1302 (e.g., copper) separated by permanent resist portions 1304 (e.g., TMMF) within dielectric layers 1306, 1308 (e.g., ABF). An example process used to fabricate the RLF patterning 1300, focusing on portion 1310 thereof, is illustrated in FIGS. 15A-15V.

FIG. 14A is an oblique view 1400 of example patterning lines 1402, 1404 on an RLF substrate 1406 fabricate by a method that does not use permanent resist. FIG. 14B is a cross-sectional view of one line 1408 of the example patterning lines 1402, 1404 of FIG. 14A. As shown in FIG. 14B, the line width and height are each about 20 micrometers. FIG. 14C is an oblique view 1410 of example patterning lines 1412, 1414 on an RLF substrate 1416 created using a permanent-resist-based patterning process. Permanent resist 1418 remains between the lines 1412, 1414 in the finished RLF. FIG. 14D is a cross-sectional view of one line 1420 of the example patterning lines 1412, 1414 of FIG. 14C. As shown in FIG. 14D, the line width and height can each be made to be much larger than the line 1408 in FIG. 14B, e.g., about 200 micrometers, while increasing (or without sacrificing) pattern density.

FIGS. 15A through 15V are cross-sectional diagrams illustrating an example permanent-resist-based patterning process used to create a portion of an RLF, such as RLF portion 1310 in FIG. 13. Only a portion of the RLF patterning is illustrated in the process of FIGS. 15A-15V; the illustrated process can be extended to form a larger RLF patterning as shown, for example, in FIG. 13. Some intermediate parts of the process, such as the multiple operations involved in seed layer patterning, photolithographic mask mounts, and resin cures, are omitted for simplicity of illustration. FIG. 15A shows a seed layer 1502 of a conductive material (e.g., copper) plated over a metal carrier 1504. As examples, the metal carrier 1504 can be made of stainless steel (SUS), another metal, or glass. FIG. 15B illustrates that the seed layer 1502 has been patterned to etch spaces in the seed layer 1502, thus forming a desired pattern of lines, such as lines 1506, 1508, in the conductive material 1502 on the metal carrier 1504. The patterning can be done, for example, according to the method illustrated in FIGS. 7A-7H, as described above. As examples, the pattern can provide conductive traces leading out away from an IC die to which the RLF can subsequently be coupled, or leading between multiple different IC dies on the RLF.

In FIG. 15C, a layer of permanent resist 1510 (e.g., TMMF) is formed over the patterned seed layer 1502 (lines 1506, 1508). Mask mount, exposure, and developing operations are performed to result in the structure shown in FIG. 15D. In FIG. 15D, windows, such as windows 1512, 1514, are opened to the thin patterned lines 1506, 1508 of the RLF, or in some regions, down to the metal carrier 1504. Also in FIG. 15D, the thin patterned lines 1506, 1508 of the RLF are bounded and separated by high, narrow walls of permanent resist, such as wall 1516. These walls of permanent resist allow the thin lines 1510, 1512 to be built up to about the height of the permanent resist walls by electroplating of the conductive material, resulting in the structure shown in FIG. 15E, having traces 1518, 1520 of much higher height and narrower space than would otherwise be possible without a permanent-resist-based process.

In FIG. 15F, a layer of dry film 1522 is laminated over the metal carrier 1504, the traces 1518, 1520, and the permanent resist walls 1516. Mask mount, exposure, and developing operations are performed to result in the structure shown in FIG. 15G, which is illustrated to have opened a window 1524 through the dry film layer 1522 down to trace 1518, but not to trace 1520. The window 1524 can be filled with a third electroplating operating to result in the structure of FIG. 15H, having a conductive contact 1526 with trace 1518. Following removal of the dry film 1522, as shown in FIG. 15I, a first layer of build-up film 1528 (e.g., ABF) can be formed to result in the structure shown in FIG. 15J. The upper surface of the resulting structure can be mechanically ground down just enough to re-expose the conductive contact 1526, without otherwise exposing traces 1518, 1520, as shown in FIG. 15K.

FIG. 15L illustrates the structure following plating of a second seed layer 1530, which can be patterned as shown in FIGS. 15M-15P. In FIG. 15M, another layer of dry film 1532 is laminated over the second seed layer. Mask mount, exposure, and developing operations open windows 1534, 1536 through the dry film layer 1532 down to the second seed layer 1530, as shown in FIG. 15N. A chemical etch can then remove the exposed portions of the second seed layer 1530, as shown in FIG. 150. In FIG. 15P, the dry film 1532 is removed, exposing the patterned seed layer 1542.

The fabrication operations shown in FIGS. 15Q-15S recapitulate the operations of FIGS. 15C-15E. In FIG. 15Q, a second layer of permanent resist 1544 (e.g., TMMF) is formed over the patterned second seed layer 1542. Mask mount, exposure, and developing operations are performed to result in the structure shown in FIG. 15R. In FIG. 15R, windows, such as window 1546, are opened through the second layer of permanent resist 1544 down to the patterned second seed layer 1542, or in some regions, down to the first layer of build-up film 1528. The patterned second seed layer 1542 is thus bounded by high, narrow walls of permanent resist, such as wall 1548. These walls of permanent resist allow the patterned second seed layer 1542 to be built up to the height of the permanent resist walls by electroplating of the conductive material, resulting in the structure shown in FIG. 15S, having thick second-layer traces, such as trace 1550.

A second layer of build-up film 1552 (e.g., ABF) can be formed to result in the structure shown in FIG. 15T. As shown in FIG. 15U, the upper surface of the resulting structure can be mechanically ground down just enough to re-expose the thick second-layer traces, such as trace 1550. As shown in FIG. 15V, the metal carrier 1504, which is not needed in the package, is removed, e.g., by mechanical grinding. The method illustrated in FIGS. 15A-15V can be extended to create the other portions of the RLF, such as is shown in FIG. 13. The examples of FIGS. 13 and 15A-15V show a two-layer lead frame, having two layers of conductive traces, such that a trace on one layer can be routed over or under a trace on the other layer. Although not illustrated, the permanent-resist-based methods can be extended, e.g., by repeating steps that are illustrated, to create lead frames having a greater number of layers, such as a three-layer RLF, a four-layer RLF, a five-layer RLF, or a six-layer RLF, as examples.

FIG. 16 is graph of line heights (thicknesses) versus line space widths for example trace patterns produced using subtractive, SAP, and MSAP methods as compared to a permanent-resist-based patterning process. As shown in the graph of FIG. 16, the results of the subtractive, SAP, and MSAP methods fall into the lower region 1602, in which comparatively larger space widths are required for higher line heights. It is not possible for subtractive, SAP, and MSAP methods to form high-aspect-ratio conductive patterns with high density. As package sizes become smaller, it is not possible to increase the density of patterning with subtractive, SAP, and MSAP methods. Upper region 1604 represents the results of permanent-resist-based patterning processes, which enable comparatively higher line heights at the same or comparatively narrower spaces. The permanent-resist-based patterning methods described herein thus enable comparatively higher heat dissipation and comparatively higher pattern density, as compared to patterning done by subtractive, SAP, and MSAP methods.

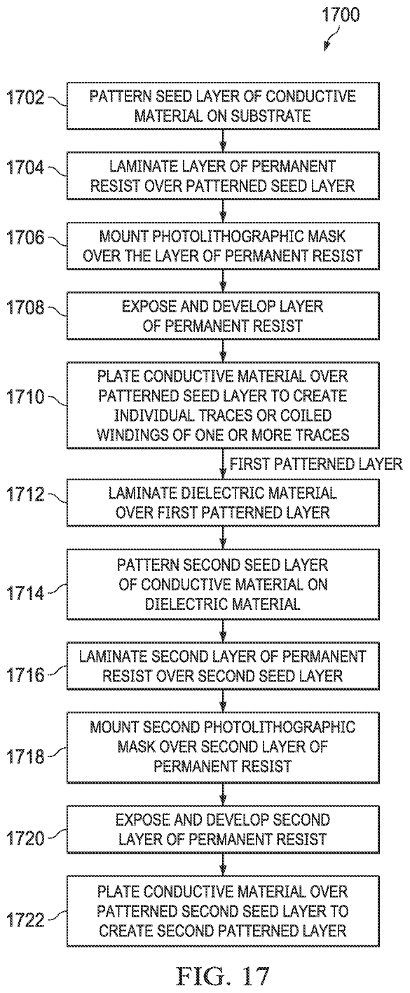

FIG. 17 is a flow chart of an example permanent-resist-based patterning method 1700. A seed layer of a conductive material (e.g., seed layer 604 in FIG. 6A) is patterned 1702 on a substrate (e.g., substrate 602 in FIG. 6A), which can be dielectric or conductive, depending on the application. The conductive material can be copper, for example. As an example, the seed layer is less than about 1.5 micrometers thick. The seed layer patterning can be done, for example, by a subtractive process as illustrated in FIGS. 7A-7H. A layer of permanent resist (e.g., permanent resist 606 in FIG. 6B) is laminated 1704 over the patterned seed layer to a thickness. The permanent resist can be TMMF, for example. A photolithographic mask (e.g., mask 608 in FIG. 6C) is mounted 1706 over the layer of permanent resist. The layer of permanent resist is exposed to a light and developed 1708, patterning the layer of permanent resist and exposing portions of the patterned seed layer (e.g., as shown in FIG. 6E). An additional amount of the conductive material (e.g., conductive material 614 in FIG. 6F) is plated 1710 over the patterned seed layer to create individual traces or coiled windings of one or more traces.

The individual traces or the windings are spaced apart from each other by at least a space width (e.g., space width 212 in FIG. 2). The individual traces or the windings have a minimum width of the conductive material that is at least a line width (e.g., line width 208 in FIG. 2). The individual traces or the windings have a minimum height of the conductive material (e.g., line height 210 in FIG. 2). As an example, the minimum height of the conductive material is greater than about 40 micrometers, e.g., greater than about 50 micrometers, e.g., greater than about 100 micrometers. As an example, the space width is less than about one-half the minimum height of the conductive material, e.g., less than about one-tenth the minimum height of the conductive material. As an example, the minimum height of the conductive material is greater than about 40 micrometers, and the space width is less than about 30 micrometers, e.g., less than about 10 micrometers. As an example, the thickness of the layer of permanent resist is greater than about 280 micrometers, the line width is greater than about 350 micrometers, and the space width is less than about 20 micrometers.

As this point in method 1700, the individual traces or coiled windings form a first patterned layer. Method 1700 can end there, or can continue to create one or more additional patterned layers. Examples of such multiple patterned layers are shown in FIG. 10, in which the multiple patterned layers are configured as primary and secondary transformer coils, and FIG. 13, in which the multiple patterned layers are configured as routed traces in an RLF. For example, the method 1700 can continue by laminating 1712 a dielectric material over the first patterned layer. The dielectric material can be a build-up film resin, as may be the case, for example, when patterning transformer coils, or can be ABF, as may be the case, for example, when patterning an RLF. A second seed layer of the conductive material (e.g., seed layer 1530, 1542 in FIGS. 15L and 15P) is patterned 1714 on the dielectric material. A second layer of permanent resist (e.g., TOK film) is laminated 1716 over the second seed layer to a second thickness. A second photolithographic mask is mounted 1718 over the second layer of permanent resist. The second layer of permanent resist is exposed to a light and developed 1720, which thus patterns the second layer of permanent resist and exposes portions of the patterned second seed layer. A second additional amount of the conductive material is plated 1722 over the patterned second seed layer to create the second patterned layer.

FIGS. 6F, 10, and 13 each illustrate example devices formed using the permanent-resist-based patterning methods described herein. Such a device includes a layer of conductive material patterned into individual traces or coiled windings. At least some of the traces or windings are lined with walls of a permanent resist that extend up to at least a minimum height of the at least some of the traces or windings. The individual traces or the windings are spaced apart from each other by at least a space width. The individual traces or the windings have a minimum width of the conductive material that is at least a line width. As an example, the minimum height of the at least some of the traces or windings is at least about 40 micrometers, e.g., at least about 50 micrometers, e.g., at least about 100 micrometers. As an example, the ratio of the line width to the space width (L/S) is greater than about 2, e.g., greater than about 10. As shown in FIGS. 10 and 13, the device can further include a second layer of conductive material patterned into individual traces or coiled windings. At least some of the traces or windings in the second layer are lined with other walls of the permanent resist that extend up to at least a minimum height of the at least some of the traces or windings in the second layer.

The device can be configured as a transformer, as shown in FIG. 10, with the first layer of patterned conductive material being configured at least in part as a first transformer coil, and with the second layer of patterned conductive material being configured at least in part as a second transformer coil that is inductively coupled to the first transformer coil. The device can be configured as an RLF, as shown in FIG. 13, with traces of the first layer of patterned conductive material being routed under traces of the second layer of patterned conductive material.

The methods and devices of the present application using a permanent resist have benefits over subtractive, SAP, and MSAP methods and devices made by subtractive, SAP, and MSAP methods, including the potential for greater minimum patterned line height. Although SAP methods laminate dry film on the top of a seed layer, the seed layer in SAP methods is not patterned. By contrast, in methods and devices that use a permanent resist, the seed layer can be patterned. In methods and devices that use a permanent resist, the space width can be less than about one-half the minimum height of the conductive material. Such a space width to line height ratio cannot be achieved by methods that use a general dry film.

In this description, the term “based on” means based at least in part on. Also, in this description, the term “couple” or “couples” means either an indirect or direct wired or wireless connection. Thus, if a first device, element, or component couples to a second device, element, or component, that coupling may be through a direct coupling or through an indirect coupling via other devices, elements, or components and connections. Similarly, a device, element, or component that is coupled between a first component or location and a second component or location may be through a direct connection or through an indirect connection via other devices, elements, or components and/or couplings. Modifications are possible in the described embodiments, and other embodiments are possible, within the scope of the claims.

What is claimed is:

1. A method comprising:
patterning a seed layer of a conductive material on a substrate;
laminating a layer of permanent resist over the patterned seed layer to a thickness;
mounting a photolithographic mask over the layer of permanent resist;
exposing to a light and developing the layer of permanent resist to pattern the layer of permanent resist, exposing portions of the patterned seed layer; and
plating an additional amount of the conductive material over the patterned seed layer to create individual traces or coiled windings of one or more traces, the individual traces or the windings spaced apart from each other by at least a space width, the individual traces or the windings having a minimum width of the conductive material that is at least a line width, the individual traces or the windings having a minimum height of the conductive material.

2. The method of claim 1, wherein the patterning the seed layer comprises:
plating the seed layer over the substrate;
laminating a layer of dry film over the seed layer;
mounting a seed-layer-patterning photolithographic mask over the dry film;
exposing to a light and developing the dry film to pattern the dry film by removing portions of the dry film, exposing portions of the seed layer underneath the removed portions of the dry film;
etching away the exposed portions of the seed layer to pattern the seed layer; and
removing the dry film.

3. The method of claim 1, wherein the minimum height of the conductive material is greater than about 50 micrometers.

4. The method of claim 1, wherein the space width is less than about one-half the minimum height of the conductive material.

5. The method of claim 1, wherein the minimum height of the conductive material is greater than about 40 micrometers, and the space width is less than about 30 micrometers.

6. The method of claim 1, wherein the thickness of the layer of permanent resist is greater than about 280 micrometers, the line width is greater than about 350 micrometers, and the space width is less than about 20 micrometers.

7. The method of claim 1, wherein the seed layer is less than about 1.5 micrometers thick.

8. The method of claim 1, wherein the permanent resist is TMMF or TMMR.

9. The method of claim 1, wherein the individual traces or coiled windings form a first patterned layer, and wherein the method further comprises forming a second patterned layer by:
laminating a dielectric material over the first patterned layer;
patterning a second seed layer of the conductive material on the dielectric material;
forming a second layer of permanent resist over the second seed layer to a second thickness;
mounting a second photolithographic mask over the second layer of permanent resist;
exposing to a light and developing the second layer of permanent resist to pattern the second layer of permanent resist, exposing portions of the patterned second seed layer; and
plating a second additional amount of the conductive material over the patterned second seed layer to create the second patterned layer.

10. The method of claim 9, wherein the dielectric material is a bismaleimide-triazine (BT) epoxy resin.

11. The method of claim 9, wherein the dielectric material is Ajinomoto Build-up Film (ABF).

12. A device comprising:
a layer of conductive material patterned into individual traces or coiled windings,
at least some of the traces or windings lined with walls of a permanent resist that extend up to at least a minimum height of the at least some of the traces or windings,
the individual traces or the windings spaced apart from each other by at least a space width, and
the individual traces or the windings having a minimum width of the conductive material that is at least a line width.

13. The device of claim 12, wherein the minimum height of the at least some of the traces or windings is at least about 40 micrometers.

14. The device of claim 13, wherein the minimum height of the at least some of the traces or windings is greater than the space width.

15. The device of claim 12, wherein the minimum height of the at least some of the traces or windings is greater than the space width.

16. The device of claim 15, wherein the minimum height of the at least some of the traces or windings is at least about 40 micrometers.

17. The device of claim 12, wherein the layer of patterned conductive material is a first layer of patterned conductive material, the device further comprising a second layer of conductive material patterned into individual traces or coiled windings, at least some of the traces or windings in the second layer being lined with other walls of the permanent resist that extend up to at least a minimum height of the at least some of the traces or windings in the second layer.

18. The device of claim 17, wherein the device is configured as a transformer, with the first layer of patterned conductive material being configured at least in part as a first transformer coil, and with the second layer of patterned conductive material being configured at least in part as a second transformer coil that is inductively coupled to the first transformer coil.

19. The device of claim 17, wherein the device is configured as a routable lead frame (RLF), with traces of the first layer of patterned conductive material being routed under traces of the second layer of patterned conductive material.

20. The device of claim 12, wherein the layer of patterned conductive material is integrated into at least one integrated circuit (IC) module comprising at least one IC die that is electrically coupled to at least one of the traces or coiled windings.
